(19) United States
(12) Patent Application Publication
(10) Pub. No.: US 2014/0339687 A1
(43) Pub. Date: Nov. 20, 2014

(54) POWER PLANE FOR MULTI-LAYERED SUBSTRATE

(71) Applicants: Shailesh Kumar, Ghazlabad (IN); Sunaina Srivastava, Delhi (IN); Swapnil Tiwari, Noida (IN); Chetan Verma, Noida (IN)

(72) Inventors: Shailesh Kumar, Ghazlabad (IN); Sunaina Srivastava, Delhi (IN); Swapnil Tiwari, Noida (IN); Chetan Verma, Noida (IN)

(21) Appl. No.: 13/894,460

(22) Filed: May 15, 2013

(51) Int. Cl. H01L 23/58

(52) U.S. Cl. CPC H01L 23/585
USPC 257/659

(57) ABSTRACT

A semiconductor device includes a ground plane and a power plane that lie in spaced, parallel planes. The power plane includes a number of openings formed around its outer edge. A ground ring surrounds the power plane and has fingers that extend towards and are received within corresponding ones of the openings of the power plane. The ground ring is electrically connected to the ground plane with vias.

### BACKGROUND OF THE INVENTION

The present invention relates to printed circuit boards and substrates for semiconductor devices, and more particularly, to a power plane for a multi-layered substrate.

Semiconductor devices and the boards to which such devices are attached typically include multiple metal layers for transmitting signals, and voltage (power and ground) between circuits and inputs/outputs (I/Os), with the metal layers being separated by insulation layers. As the number of transistors per device increases, the signal traces in the various metal layers have increased. Furthermore, integrated circuits are operated using higher clock speeds. These factors have made it a challenge to solve electromagnetic interference (EMI) problems associated with the higher clock speeds and more highly integrated circuits. Switching of electronic circuits leads to transitions in resultant signal and power profiles. These transitions are accompanied by electromagnetic radiation. Therefore, an objective of the engineers designing these circuits is to reduce the electromagnetic radiations, and at the same time, include maximum signal and power spectra in the circuits.

Electromagnetic radiation or interference (EMI) often is introduced due to imperfect electromagnetic coupling between the power and ground planes of the semiconductor device. EMI can interfere with and affect the operation of external circuits that are in proximity of the semiconductor device. A number of techniques have been proposed to overcome EMI problems. The most common technique includes increasing the area of the power and ground planes and mounting one or more bypass capacitors therebetween. However, with chip and package sizes decreasing, it is becoming impracticable to have power and ground planes with increased areas. In addition, the bypass capacitors increase the overall size and complexity of the semiconductor device.

FIG. 1 is a schematic diagram of a conventional multi-layered semiconductor device 100 designed to reduce EMI. The device has a power plane 102, a ground plane 104, and a guard ring 106 that surrounds a power plane 102. Layers of suitable insulating materials (not shown) are provided between the power and ground planes 102 and 104. A clearance is maintained between the power and ground planes 102 and the guard ring 106. The guard ring 106 is connected to the ground plane 104 by way of a plurality of vias 108. As can be seen in FIG. 1, the guard ring 106 and the power plane 102 lie in the same plane and the ground plane 104 is in a different, parallel plane, separated by an insulating layer. As a result, radiation occurs between the power plane 102 and the guard ring 106. It is desirable to suppress the radiation to outside the package. Electromagnetic waves generated at the power plane 102 are terminated at the guard ring 106 due to a potential difference between the guard ring 106 and the power plane 102.

The electromagnetic radiations can be classified into reactive field, near-field and far-field radiations. The reactive field is a region immediately surrounding the source of radiation, the near-field is a region beyond the reactive field, and the far-field is a region beyond the near-field. Typically, far-field radiations are identified with the electromagnetic radiation that radiates to other semiconductor devices in proximity to the device 100. The conventional semiconductor device 100 emits considerable far-field and near-field radiation. These emissions are reduced only at a periphery of the power plane 102. In addition, the resonant frequency of the conventional semiconductor device 100 is low. As the intensity of radiations reaches a maximum at the resonant frequency, it is desirable that the resonant frequency of the device 100 is high, as it will be away from a band of operation of the circuits placed in proximity to the device 100.

Therefore, it would be advantageous to have a multi-layered semiconductor device with reduced near-field and far-field electromagnetic radiations and a higher resonant frequency, that reduces area overhead, and that eliminates the above mentioned disadvantages of conventional multi-layered semiconductor devices.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 illustrates an isometric view of a conventional multi-layered semiconductor device designed to reduce electromagnetic radiation;

FIG. 2 is an isometric view of a multi-layered semiconductor device in accordance with an embodiment of the present invention;

FIG. 3 is a top view of a power plane and a ground ring of the multi-layered semiconductor device of FIG. 2; and

FIG. 4 is a cross-sectional view of the multi-layered semiconductor device of FIG. 2 taken along plane X-X′ (FIG. 3), in accordance with an embodiment of the present invention.

### DETAILED DESCRIPTION OF PREFERRED EMBODIMENTS

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a semiconductor device is provided. The semiconductor device includes first and second spaced, parallel conductive planes. The second conductive plane has a plurality of openings formed along its peripheral edge. A ground ring is formed in the same plane as the second conductive plane and surrounds the second conductive plane. The ground ring has a plurality of fingers that extend from an inner peripheral edge thereof towards corresponding ones of the openings in the second conductive plane. In one embodiment, the first plane is a ground plane and the second plane is a power plane. In another embodiment, signal layers in parallel planes above and below the first and second conductive planes. In yet another embodiment, the first conductive plane and the ground ring are electrically connected with a plurality of vias. The invention may be embodied in, for example, a surface mount semiconductor device or a printed circuit board (PCB).

Various embodiments of the present invention provide a multi-layered semiconductor device that includes ground and power planes separated by a predetermined distance. A ground ring is formed in the same plane as the power plane and has a plurality of fingers that extend from the inner peripheral edge thereof towards corresponding ones of the plurality of openings formed in the outer peripheral edge of the power plane. The plurality of fingers interlace with the plurality of openings. This arrangement allows for increased coupling between the power plane and the ground ring, leading to a higher resonant frequency and reduced near-field and far-field radiations generated at the power plane. As the areas of the power and ground planes are not increased (in comparison to the conventional design), the resultant semiconductor device is compact in size. In addition, as the far-field radiations are low, and thus do not interfere with other, proximate semiconductor devices or circuits.

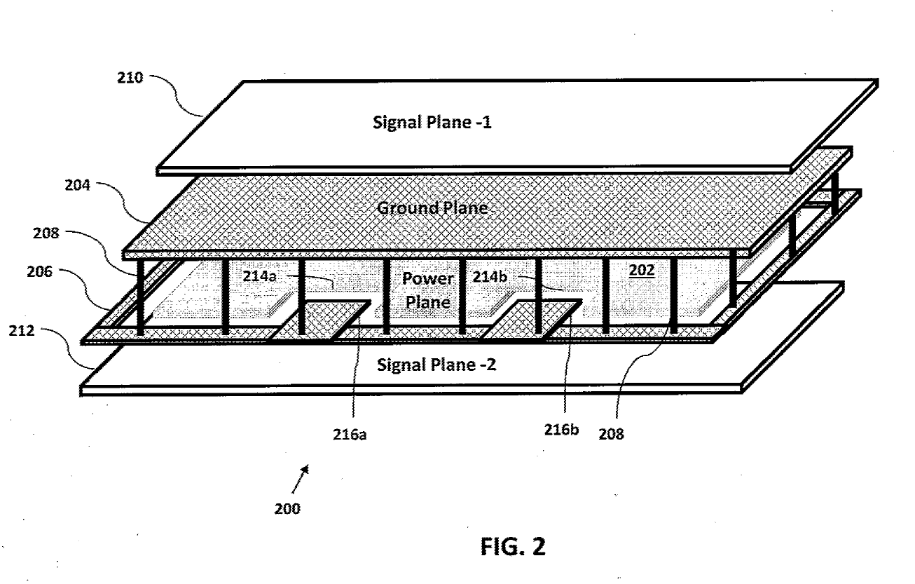

Referring now to FIG. 2, an isometric view of a multi-layered semiconductor device 200 in accordance with an embodiment of the present invention is shown. The semiconductor device has a power plane 202 and a ground plane 204. The power and ground planes 202 and 204 lie in spaced, parallel planes. A ground ring 206 lies in the same plane and surrounds the power plane 202.

The ground ring 206 is electrically connected to the ground plane 204 with a plurality of vias 208 that are spaced along the peripheries of the ground plane 204 and the ground ring 206. The vias 208 are made of a conductive material, such as a metal and may be covered with an insulating material (not shown).

A third conductive plane or first signal layer 210 is formed over the ground plane 204. The first signal layer 210 is spaced from and parallel to the ground plane 204. Similarly, a fourth conductive plane or second signal layer 212 is formed below the power plane 202. The second signal layer 212 is parallel to and spaced from the power plane 202. The first and second signal layers 210, 212 are used to transmit digital logic (or analog) signals between various circuits, as is well understood by those of skill in the art.

Although not shown, each of the parallel planes, including the power and ground planes 202, 204, the ground ring 206, and the first and second signal layers 210, 212 is separated from its neighbour by a layer of insulative material having a thickness and dielectric constant suitable for insulating the layers one from another, as is known by those of ordinary skill in the art. Further, the device 200 may include additional signal layers, not shown.

The power plane 202 has a plurality of openings 214a, 214b (collectively referred to as openings 214) formed along its outer peripheral edge and the ground ring 216 has a plurality of fingers 216a and 216b (collectively referred to as fingers 216) that extend from its inner peripheral edge towards corresponding ones of the openings 214. The ground ring 206 is arranged around the power plane 202 such that the fingers 216 are interlaced with corresponding one of the openings 214. A clearance, however, is maintained between the openings and fingers 214, 216, and between the power plane 202 and surrounding ground ring 206 for providing appropriate insulation.

It should be noted that only two fingers 216 and corresponding openings 214 are shown here for illustrative purposes only and it should be understood by those of skill in the art that any suitable number of fingers 216 and corresponding openings 214 may be provided. Further, the ground ring 206 is shown as substantially rectangular; however, depending on the geometry and requirements of the semiconductor device 200, other shapes are possible. The fingers 216 and corresponding openings 214 are shown as substantially rectangular; however, variations of their shapes also are possible, as long as the two are designed to interlace with each other.

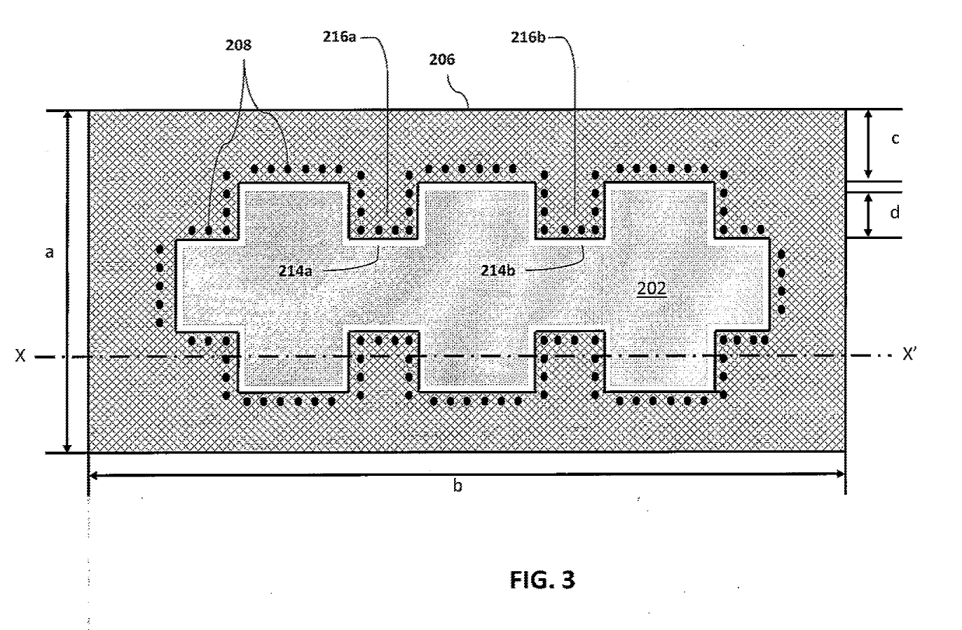

FIG. 3 is a top plan view of the power plane 202 and the ground ring 206 of the multi-layered semiconductor device 200 in accordance with an embodiment of the present invention. The ground ring 206 is substantially rectangular in shape, with a width ‘a’ and length ‘b’. For example, the width ‘a’ may be about 120 to 130 millimeters and the length ‘b’ also may be about 120 to 130 millimeters.

The ground ring 206 has a plurality of fingers 216 that extend from its inner peripheral edge towards the power plane 202. The power plane 202 has a corresponding plurality of openings 214. The fingers 216 are interlaced with corresponding ones of the openings 214, as shown in FIG. 3. The ground ring has a width ‘c’ and the fingers 216 have a length ‘d’. For example, in an embodiment of the present invention, the width ‘c’ of the ground ring 206 may be about 2.5 millimeters and the length ‘d’ of the fingers 216 may be about 6.3 to 6.4 millimeters. In another embodiment, the width ‘c’ may be about 15 to 18 millimeters and the length ‘d’ may be about 15 to 18 millimeters. The vias 208 are placed around the periphery of the ground ring 206 and the fingers 216, as shown in FIG. 3. A skilled artisan will appreciate that the dimensions shown here are for illustrative purpose only and they do not restrict the scope of the invention in any way.

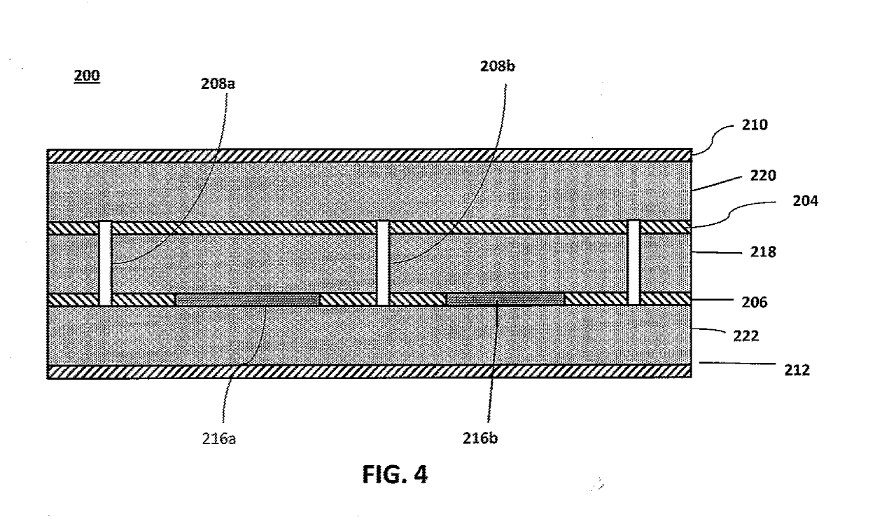

FIG. 4 is a cross-sectional view of the multi-layered semiconductor device 200 taken along line X-X′ of FIG. 3. As can be seen from FIG. 4, the device 200 includes a first insulating layer 218 that separates the power plane 202 and the ground plane 204. The vias 208 extend from the ground plane 204 to the ground ring 206 through the first insulating layer 218. Similarly, a second insulating layer 220 is formed between the ground plane 206 and the first signal layer 210, while a third insulating layer 222 is formed between the power plane 202 and the second signal layer 212.

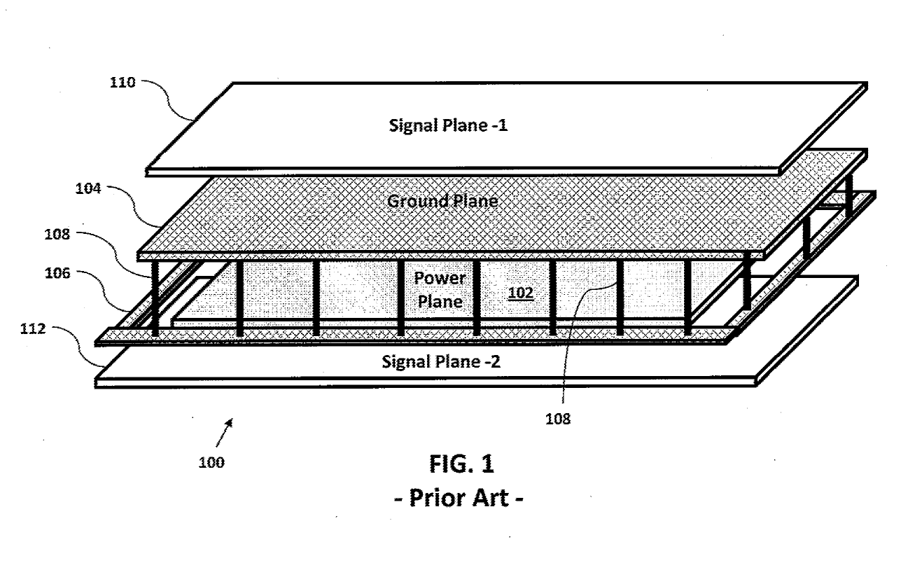

In one embodiment, a semiconductor device was fabricated and tested, and exhibited a maximum emission of 15.48 V/MHz at a resonant frequency of 154 MHz. This is a significant improvement over a similar device fabricated in accordance with the conventional design explained in conjunction with FIG. 1, which exhibited a maximum emission of 27.08 V/MHz at a resonant frequency of 150 MHz. Thus, the design of the present invention increases the coupling between the power plane 202 and the ground ring 206, leading to a higher resonant frequency and reduced near-field and far-field radiations generated at the power plane 202.

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It should be understood that, although the terms first, second, etc. and horizontal and vertical are used to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. A semiconductor device, comprising:
first and second spaced, parallel conductive planes, wherein the second conductive plane has a plurality of fingers and openings formed along a peripheral edge thereof; and
a ground ring that lies in the same plane as the second conductive plane and surrounds the second conductive plane, wherein the ground ring has a plurality of fingers that extend from an inner peripheral edge thereof into corresponding ones of the plurality of openings of the second conductive plane so that the fingers of the second conductive plane and the ground ring are at least partially interlaced.

2. The semiconductor device of claim 1, wherein the first conductive plane is a ground plane.

3. The semiconductor device of claim 2, wherein the second conductive plane is a power plane.

4. (canceled)

5. The semiconductor device of claim 1, wherein the ground ring is connected to the first conductive plane by way of a plurality of vias.

6. The semiconductor device of claim 1, further comprising an insulating layer disposed between the first and second conductive planes.

7. The semiconductor device of claim 1, further comprising a third conductive plane formed over the first conductive plane and a fourth conductive plane formed below the second conductive plane, wherein the third and fourth conductive planes are parallel to and spaced from the first and second conductive planes.

8. The semiconductor device of claim 7, wherein each of the third and fourth conductive planes is a signal plane.

9. The semiconductor device of claim 7, further comprising a first insulating layer disposed between the first and third conductive planes and a second insulating layer disposed between the second and fourth conductive planes.

10. The semiconductor device of claim 1, wherein the semiconductor device is one of a ball grid array (BGA) package, a printed circuit board (PCB), and a surface mount package.

11. A semiconductor device, comprising:
a ground plane;
a power plane that is spaced from and parallel to the ground plane, wherein the power plane has a plurality of fingers and openings formed in a peripheral edge thereof;
a ground ring that lies in the same plane as the power plane and surrounds the power plane, wherein the ground ring has a plurality of fingers that extend from inner edge thereof towards corresponding ones of the openings in the power plane so that the fingers of the power plane and the ground ring are at least partially interlaced; and
a plurality of vias that extend from the ground plane to the ground ring for electrically connecting the ground plane to the ground ring.

12. (canceled)

13. The semiconductor device of claim 11, further comprising an insulating layer disposed between the ground and power planes.

14. The semiconductor device of claim 11, further comprising a first signal layer formed over and parallel to the ground plane and a second signal layer formed below and parallel to power plane.

15. The semiconductor device of claim 14, further comprising a first insulating layer disposed between the ground plane and the first signal layer and a second insulating layer disposed between the power plane and the second signal layer.

16. The semiconductor device of claim 11, wherein the semiconductor device is one of a ball grid array (BGA) package, a printed circuit board (PCB), and a surface mount package.

17. A semiconductor device, comprising:
a ground plane;
a power plane that is parallel to and spaced from the ground plane, wherein the power plane has a plurality of openings formed along a peripheral edge thereof;
a first insulating layer disposed between and separating the ground plane and the power plane;
a first signal layer formed over and parallel to the ground plane;
a second insulating layer disposed between the ground plane and the first signal layer;
a second signal layer formed below and parallel to the power plane;
a third insulating layer disposed between the power plane and the second signal layer;
a ground ring that lies in the same plane as the power plane and surrounds the power plane, wherein the ground ring has a plurality of fingers that extend from inner edge thereof towards and into corresponding ones of the openings in the power plane so that the fingers of the power plane and the ground ring are at least partially interlaced; and
a plurality of vias extending from the ground plane to the ground ring through the first insulating layer, for electrically connecting the ground plane to the ground ring.

18. The semiconductor device of claim 17, wherein the semiconductor device is one of a ball grid array (BGA) package, a printed circuit board (PCB), and a surface mount package.
